(19) United States
(12) Patent Application Publication
(10) Pub. No.: US 2023/0229133 A1
(43) Pub. Date: Jul. 20, 2023

(54) SEMICONDUCTOR MACHINE SYSTEM AND MANUFACTURING METHOD USING THEREOF

(71) Applicant: TENGXI TECHNOLOGY CO. LTD., Zhubei City (TW)

(72) Inventors: WEI-HAN LO, Hsinchu City (TW); TIEN-HSIANG HO, Taoyuan City (TW)

(21) Appl. No.: 18/146,505

(22) Filed: Dec. 27, 2022

Related U.S. Application Data
(60) Provisional application No. 63/300,073, filed on Jan. 17, 2022.

(51) Int. Cl. G05B 19/18; H01L 21/67; H01J 37/32; G03F 7/42

(52) U.S. Cl. CPC G05B 19/188; H01L 21/67225; H01J 37/32899; H01J 37/32082; H01J 37/32449; G03F 7/427; H01J 2237/20278; H01J 37/32816; H01J 2237/20214; H01J 2237/20235; H01J 2237/186; H01J 2237/002; H01J 37/32733; G05B 2219/45031

(57) ABSTRACT

A semiconductor machine system comprises a plurality of working chambers, wherein the working chambers process materials separately; a control host coupled to the plurality of working chambers, comprising: a main control module coupled to the plurality of working chambers; an analog control module coupled to the plurality of working chambers, and the analog control module is detachably coupled to one or more external devices by serial interface coupling; a digital control module coupled to the plurality of working chambers, and the main control module, the analog control module and the digital control module are coupled to each other; and a plurality of operating units coupled to at least one of the main control module, the analog control module and the digital control module, respectively, to control the plurality of working chambers for processing the materials by the main control module, the analog control module and the digital control module.

### FIELD

The present disclosure generally relates to the control structure composition of the semiconductor machine system and manufacturing method using thereof.

### BACKGROUND

With the rapid progress of the semiconductor industry, electronic products are becoming increasingly compact and powerful. The manufacturing process of semiconductor integrated circuits often requires many precise processing steps to define and form circuit elements and circuit layouts on the wafer. The large number of processing steps requires many production machines and processing control. Therefore, in order to effectively control the semiconductor production processing, semiconductor manufacturers are constantly developing new monitoring methods and monitoring systems to improve processing yields, product yields, quality, reliability, and reduce product costs to maintain their competitiveness. However, referring to FIG. 1, the electronic control system of the general semiconductor machine 30 must be connected to the external sensing modules or other control machines through wiring. If there are too many sensing modules or control machines to be connected, the semiconductor machine 30 must be equipped with multiple interface cards (31, 31′ . . . ), and then connected to the sensing modules or control machines through these interface cards (31, 31′ . . . ), respectively, which would cause complicated troubles in wiring between the semiconductor machine 30 and each external module or control machine, and moreover, the semiconductor machine is not able to accurately give feedback signals when controlling the mechanical arm, resulting in the inability to achieve more precise control of the mechanical arm.

### SUMMARY

In view of the above, it is necessary to provide a semiconductor machine that can reduce the coupling complexity, precisely control the operations of the mechanical arm, and effectively reduce the overall size of the machine.

According to the present disclosure, a semiconductor machine system is provided. the semiconductor machine system, comprising: a plurality of working chambers, wherein the plurality of working chambers process materials separately; and a control host coupled to the plurality of working chambers, which comprises: a main control module coupled to the plurality of working chambers; an analog control module coupled to the plurality of working chambers, wherein the analog control module is detachably coupled to one or more external devices by serial interface coupling; a digital control module coupled to the plurality of working chambers, wherein the main control module, the analog control module and the digital control module are coupled to each other; and a plurality of operating units coupled to at least one of the main control module, the analog control module and the digital control module, respectively, to control the plurality of working chambers for processing the materials by the main control module, the analog control module and the digital control module.

According to an embodiment of the present invention, the plurality of working chambers comprises at least one of a primary photoresist stripping chamber, a secondary photoresist stripping chamber, a wafer transfer chamber, a wafer exchange chamber, and a wafer cooling chamber; wherein the main control module is coupled to at least one of the primary photoresist stripping chamber, the secondary photoresist stripping chamber, the wafer transfer chamber, the wafer exchange chamber, and the wafer cooling chamber, respectively, for control; the analog control module is coupled to at least one of the primary photoresist stripping chamber, the secondary photoresist stripping chamber, the wafer transfer chamber, and the wafer exchange chamber, respectively, for control; and the digital control module is coupled to at least one of the primary photoresist stripping chamber, the secondary photoresist stripping chamber, the wafer transfer chamber, the wafer exchange chamber, and the wafer cooling chamber, respectively, for control.

According to an embodiment of the present invention, the plurality of operating units further comprises: a RF plasma unit, which comprises a plasma generator and a control circuit; a gas control unit, which comprises a solenoid valve, a flow valve, and a barometer; and a main control unit, which comprises a processor and a storage device, wherein the storage device is coupled to the processor and stores a plurality of instructions which, when executed by the processor, cause the processor to control the RF plasma unit, the gas control unit, and the plurality of working chambers.

According to an embodiment of the present invention, the main control module is coupled to the RF plasma unit, the main control unit, and the gas control unit, respectively, the analog control module is coupled to the RF plasma unit and the gas control unit, respectively, and the digital control module is coupled to the RF plasma unit, the main control unit, and the gas control unit.

According to an embodiment of the present invention, the semiconductor machine system further comprising: a mechanical arm, which uses a servo motor as a driving power source, and the control host receives feedback signals from the mechanical arm in real time.

According to the present disclosure, a manufacturing method utilizing a semiconductor machine system is provided. The manufacturing method utilizing a semiconductor machine system, comprising the following steps: driving a wafer exchange chamber of the semiconductor machine system by a main control unit and a gas control unit of the semiconductor machine system so that the wafer exchange chamber is depressurized, placed with materials, and vacuumed before opening; controlling a wafer transfer chamber of the semiconductor machine system by the main control unit so that a mechanical arm of the semiconductor machine system carries the materials and moves to a positioning position; and controlling the wafer transfer chamber by the main control unit so that the mechanical arm picks and places a board, and after placing the materials in photoresist stripping chambers of the semiconductor machine system, a plasma processing is performed on the materials by a RF plasma unit of the semiconductor machine system.

According to an embodiment of the present invention, the manufacturing method further comprising: confirming whether new materials are placed in a shuttle chamber; if the new material has been placed, after the main control unit and the gas control unit control the wafer exchange chamber to be vacuumed, a carrying platform in the wafer exchange chamber moves downward in a rotational manner; and if the new material is not placed, the main control unit confirms whether to continue the manufacturing method by a display screen.

According to an embodiment of the present invention, the manufacturing method further comprising: controlling an opening timing of vacuum air valves of a primary photoresist stripping chamber (back chamber) and a secondary photoresist stripping chamber (side chamber) by the main control unit and the gas control unit.

According to an embodiment of the present invention, the manufacturing method further comprising: controlling a wafer carrier exchange table in the wafer exchange chamber to exchange the materials by the main control unit, and when the wafer carrier exchange table reaches the positioning position, the wafer carrier exchange table raises in a rotational manner; controlling the movement of the mechanical arm by the main control unit; and driving the wafer exchange chamber to open after depressurized by the main control unit and the gas control unit.

According to an embodiment of the present invention, the manufacturing method further comprising: after the plasma processing performed on the materials is finished by the RF plasma unit, the main control unit controls the wafer cooling chamber of the semiconductor machine system to control a cooling time.

### BRIEF DESCRIPTION OF THE DRAWINGS

FIG. 1 is a schematic view of wiring of a conventional semiconductor machine.

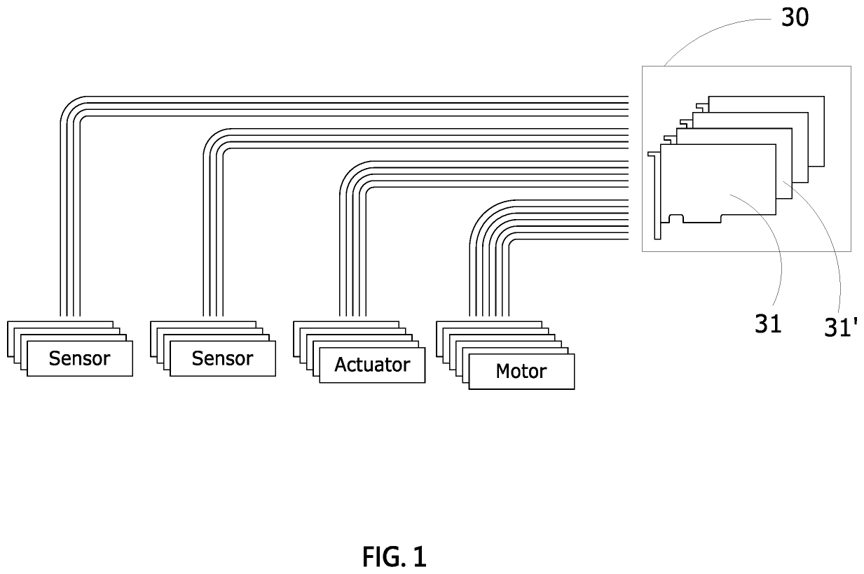

FIG. 2 is a schematic view of the composition of the semiconductor machine system.

FIG. 3 is a schematic view of the composition of the plurality of working chambers.

FIG. 4 is a schematic view of the composition of the plurality of operating units.

FIG. 5 is a schematic view of the coupling state of the main control module.

FIG. 6 is a schematic view of the coupling state of the analog control module.

FIG. 7 is a schematic view of the coupling state of the digital control module.

FIG. 8 is a schematic view of the composition of the semiconductor machine system in accordance with one embodiment of the present invention.

FIG. 9 is a schematic view of the coupling of the analog control module.

FIG. 10 is the processing method and steps of the semiconductor machine system.

FIG. 11 is a flowchart of the workflow processing steps.

### DETAILED DESCRIPTION

The following disclosure contains specific information pertaining to exemplary embodiments in the present disclosure. The drawings and the accompanying detailed description in the present disclosure are merely for exemplary embodiments. However, the present disclosure is not limited to these exemplary embodiments. Other variations and embodiments of the present invention would occur to those skilled in the art. Unless noted otherwise, identical or corresponding elements in the drawings may be indicated by identical or corresponding reference numerals. Moreover, the drawings and embodiments in the present invention are generally not drawn to scale and are not correspond to actual relative dimensions.

For purpose of consistency and ease of understanding, the same features (although, in some examples, not shown) are indicated by numerals in the exemplary drawings. However, the features in different embodiments may be differed in other respects, and thus should not be narrowly limited to what is shown in the drawings.

The terms “at least one embodiment”, “one embodiment”, “multiple embodiments”, “different embodiments”, “some embodiments,” “present embodiment”, and the like may indicate that an embodiment of the present invention so described may include a particular feature, structure or characteristic, but not every possible embodiment of the present invention must include a particular feature, structure or characteristic. Moreover, the repeated use of the phrases “in one embodiment”, “in the present embodiment” does not necessarily mean the same embodiment, although they may be identical. Furthermore, the use of phrases such as “embodiments” in connection with “the present invention” does not mean that all embodiments of the present invention necessarily include a particular feature, structure or characteristic, and should be understood as “at least some embodiments of the present invention” includes the particular feature, structure or characteristic described. The term “coupling” or “coupled” is defined as a connection, directly or indirectly through intermediate elements, and is not necessarily limited to physical connections. When the term “comprise” or “comprising” is used, it means “including but not limited to”, which specifically indicates the open inclusion or relationship of the combinations, groups, series and equivalents.

Those skilled in the art will immediately recognize that any computing functions or algorithm described in the present invention may be implemented by hardware, software or a combination of software and hardware. The modules corresponding to the described functions may be software, hardware, firmware or any combination thereof. The software implementation may comprise computer-executable instructions stored on a computer-readable medium such as memory or other types of storage. For example, one or more microprocessors or general-purpose computers with communication processing capabilities may be programmed with corresponding executable instructions to design and execute the described network functions or algorithms. The processors, microprocessors, or general-purpose computers may be formed by applications specific integrated circuitry (ASIC), programmable logic arrays, and/or using one or more digital signal processors (DSPs). Although several exemplary embodiments described in the specification are directed toward software installed and executed on computer hardware, alternative exemplary embodiments with firmware or hardware or a combination of hardware and software are also within the scope of the present invention.

The storage device may be a computer-readable medium, which includes but not limited to random access memory (RAM), Read Only Memory (ROM), erasable programmable read-only memory (EPROM), electrically erasable programmable read-only memory (EEPROM), flash memory, compact disc read-only memory (CD ROM), magnetic cartridge, magnetic tape, disk memory or any other equivalent medium capable of storing computer-readable instructions.

Furthermore, the various electronic devices of the present invention may be coupled to each other by customized protocols or following existing standards or de facto standards, including but not limited to Ethernet, IEEE 802.11 or IEEE 802.15 series, wireless USB or telecommunication standards. In addition, the various devices of the present invention may also respectively comprise any device configured to transmit and/or store data to and receive data from a computer-readable medium. In addition, the various devices of the present invention may include a computer system interface that may enable data to be stored on or received from a storage device. For example, each device of the present invention may include chipsets supporting peripheral component interconnect (PCI) and peripheral component interconnect express (PCIe) bus protocols, dedicated bus protocols, universal serial bus (USB) protocols, I2C, or any other logical and physical structure that may be used to interconnect peer devices.

In addition, for explanatory and non-limiting purposes, specific details such as functional entities, techniques, protocols, standards, etc., are set forth to provide an understanding of the described technologies. In other embodiments, detailed descriptions of well-known methods, techniques, systems, architectures, etc. are omitted to avoid the description being confused by unnecessary details.

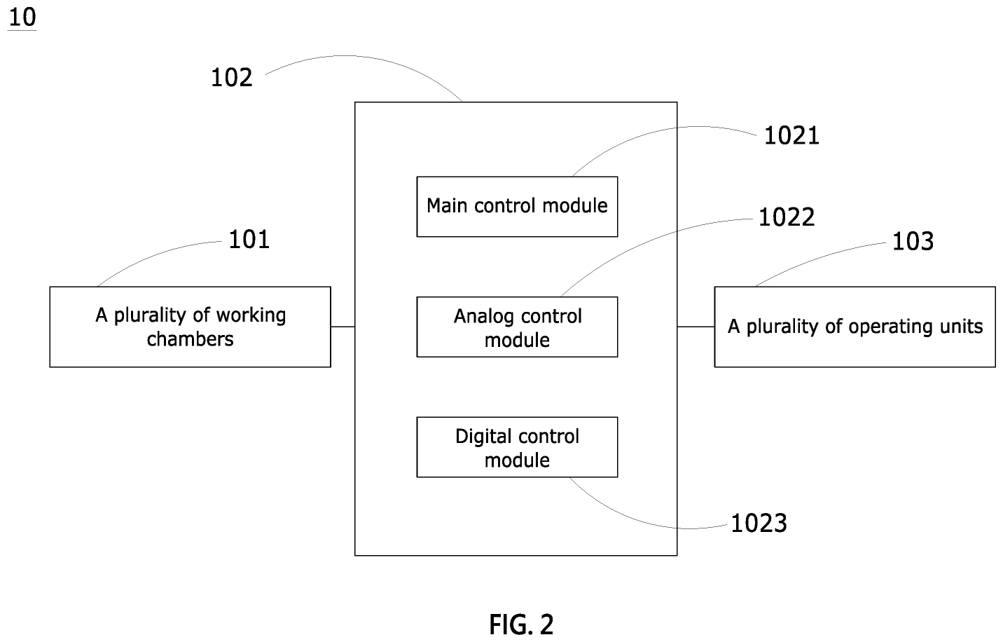

FIG. 2 is a schematic view of the composition of the semiconductor machine system. Referring to FIG. 2, the semiconductor machine system 10 comprises a plurality of working chambers 101, a control host 102, and a plurality of operating units 103. Each of the plurality of working chambers 101 processes materials, such as wafers, separately. The control host 102 is coupled to the plurality of working chambers 101, and the operating system of the control host 102 may, for example, use Windows 10 IoT to accommodate the loading of various operating software and various operating conditions, and to maintain control stability and facilitate the acquisition of relevant materials for subsequent host maintenance. In addition, software development may be performed, for example, by Microsoft Visual Studio. The control host 102 comprises: a main control module 1021 coupled to the plurality of working chambers 101; an analog control module 1022 coupled to the plurality of working chambers 101, wherein the analog control module 1022 is detachably coupled to one or more external devices by serial interface coupling; and a digital control module 1023 coupled to the plurality of working chambers 101, wherein the main control module 1021, the analog control module 1022, and the digital control module 1023 are coupled to each other. The plurality of operating units 103 are coupled to at least one of the main control module 1021, the analog control module 1022 and the digital control module 1023, respectively to control the plurality of working chambers 101 for processing the material by the main control module 1021, the analog control module 1022, and the digital control module 1023. In one embodiment, the main control module 1021 may be an industrial PC (IPC) main control module, the analog control module 1022 may be an analog input output (AIO) module, the digital control module 1023 may be a digital input output (DIO) module.

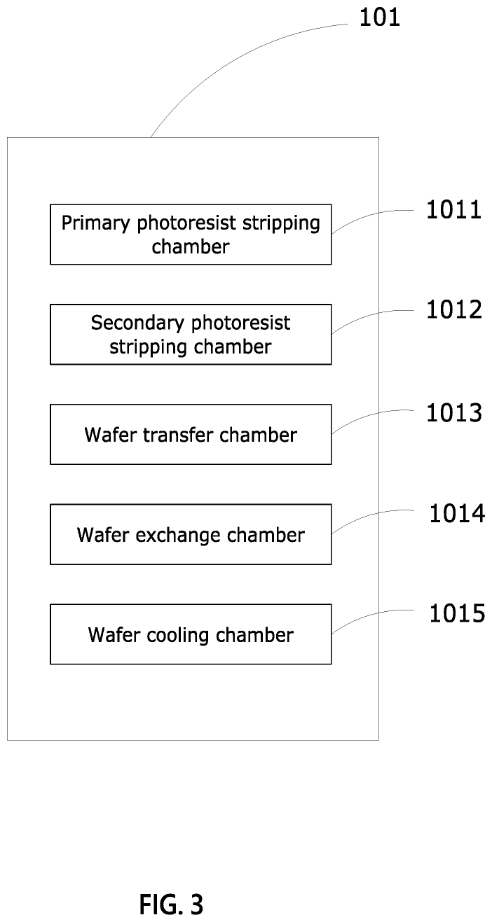

FIG. 3 is a schematic view of the composition of the plurality of working chambers. Referring to FIG. 3, in one embodiment, the plurality of working chambers 101 comprises at least one of a photoresist stripping chamber, a wafer transfer chamber 1013, a wafer exchange chamber 1014, and a wafer cooling chamber 1015, and the photoresist stripping chamber may further comprise at least one of a primary photoresist stripping chamber 1011 and a secondary photoresist stripping chamber 1012. The primary photoresist stripping chamber 1011 provides dry photoresist stripping etching by radio frequency (RF) plasma. The secondary photoresist stripping chamber 1012 provides dry photoresist stripping etching by RF plasma. The wafer transfer chamber 1013 provides for the use of mechanical arms to move wafers to other related mechanisms. The wafer exchange chamber 1014 comprises a shuttle chamber and provides for the exchange of inner and outer wafer carriers by a carrying mechanism. The wafer cooling chamber 1015 provides cooling to the temperature generated by the photoresist stripping process.

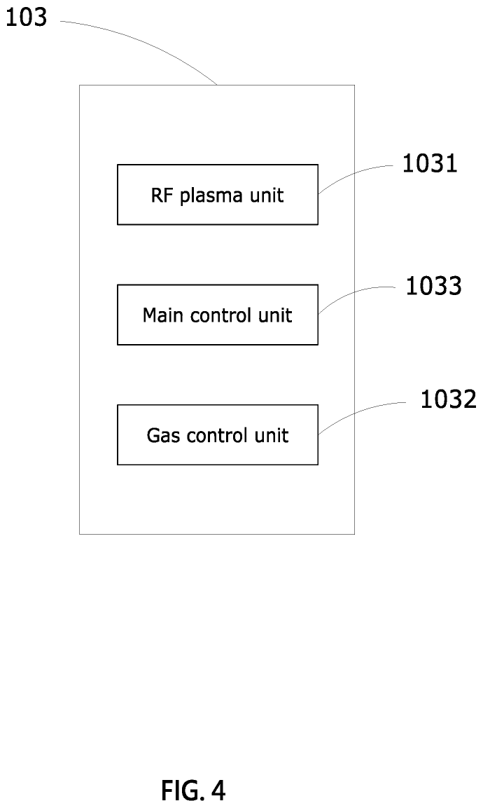

FIG. 4 is a schematic view of the composition of the plurality of operating units. Referring to FIG. 4, in one embodiment, the plurality of operating units 103 further comprise an RF plasma unit 1031, a gas control unit 1032, and a main control unit 1033. The RF plasma unit 1031 comprises a plasma generator and a control circuit. The gas control unit 1032 comprises a solenoid valve, a flow valve, and a barometer. The main control unit 1033 comprises a processor and a storage device, wherein the storage device is coupled to the processor and stores a plurality of instructions which, when executed by the processor, cause the processor to control the RF plasma unit 1031, the gas control unit 1032, and the plurality of working chambers 101.

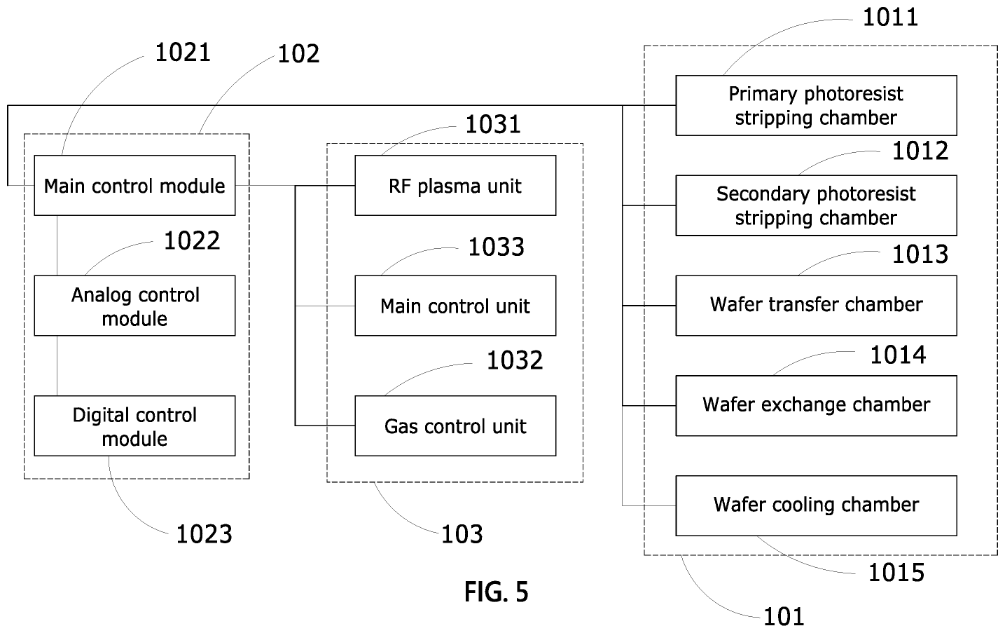

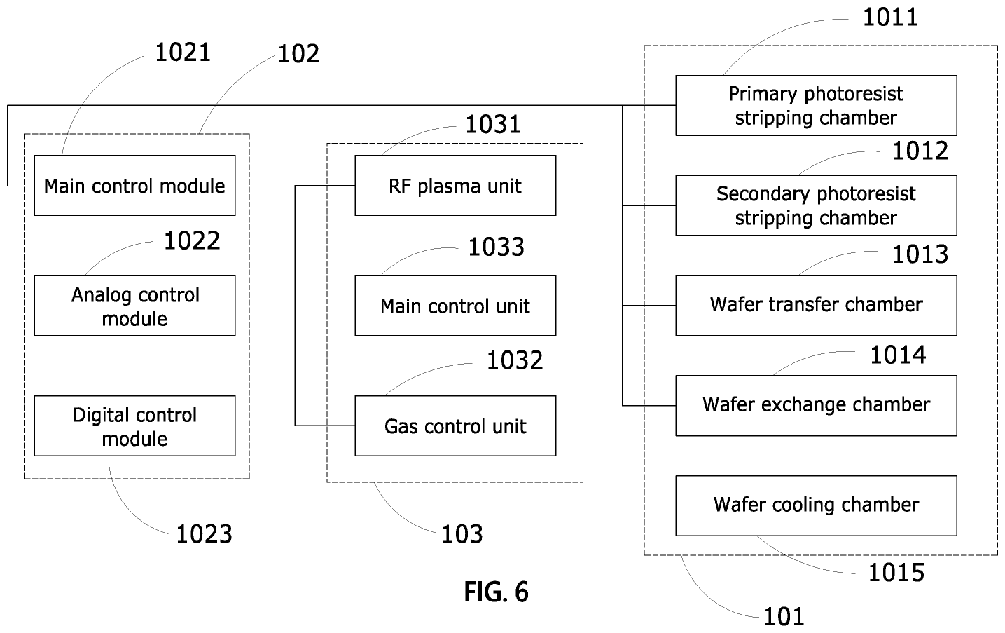

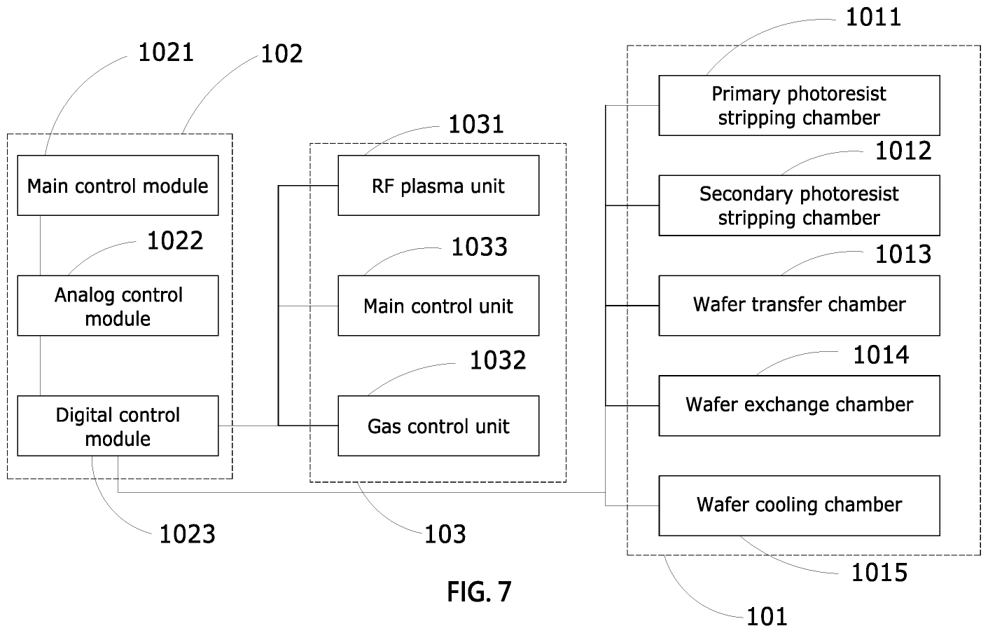

FIG. 5 is a schematic view of the coupling state of the main control module. FIG. 6 is a schematic view of the coupling state of the analog control module. FIG. 7 is a schematic view of the coupling state of the digital control module. Referring to FIGS. 5 to 7, the main control module 1021 is coupled to at least one of the primary photoresist stripping chamber 1011, the secondary photoresist stripping chamber 1012, the wafer transfer chamber 1013, the wafer exchange chamber 1014, and the wafer cooling chamber 1015, respectively, for control; the analog control module 1022 is coupled to at least one of the primary photoresist stripping chamber 1011, the secondary photoresist stripping chamber 1012, the wafer transfer chamber 1013, and the wafer exchange chamber 1014, respectively, for control; and the digital control module 1023 is coupled to at least one of the primary photoresist stripping chamber 1011, the secondary photoresist stripping chamber 1012, the wafer transfer chamber 1013, the wafer exchange chamber 1014, and the wafer cooling chamber 1015, respectively, for control.

Referring to FIGS. 5 to 7, the main control module 1021, the analog control module 1022, and the digital control module 1023 mainly cooperate with the RF plasma unit 1031, the main control unit 1033, and the gas control unit 1032, respectively, to operate the working chambers 101, and the main control module 1021 mainly provides the applications of equipment process, data processing, and human-machine interface. In one embodiment, the main control module 1021 is further coupled to the RF plasma unit 1031, the gas control unit 1032, and the main control unit 1033, respectively, to simultaneously control the operating units 103 and the working chambers 101. The analog control module 1022 is further coupled to the RF plasma unit 1031 and the gas control unit 1032, respectively. The digital control module 1023 is further coupled to the RF plasma unit 1031, the gas control unit 1032, and the main control unit 1033. Therefore, the main control module 1021, the analog control module 1022, and the digital control module 1023 may respectively or simultaneously control the operations of the operating units 103 and the working chambers 101.

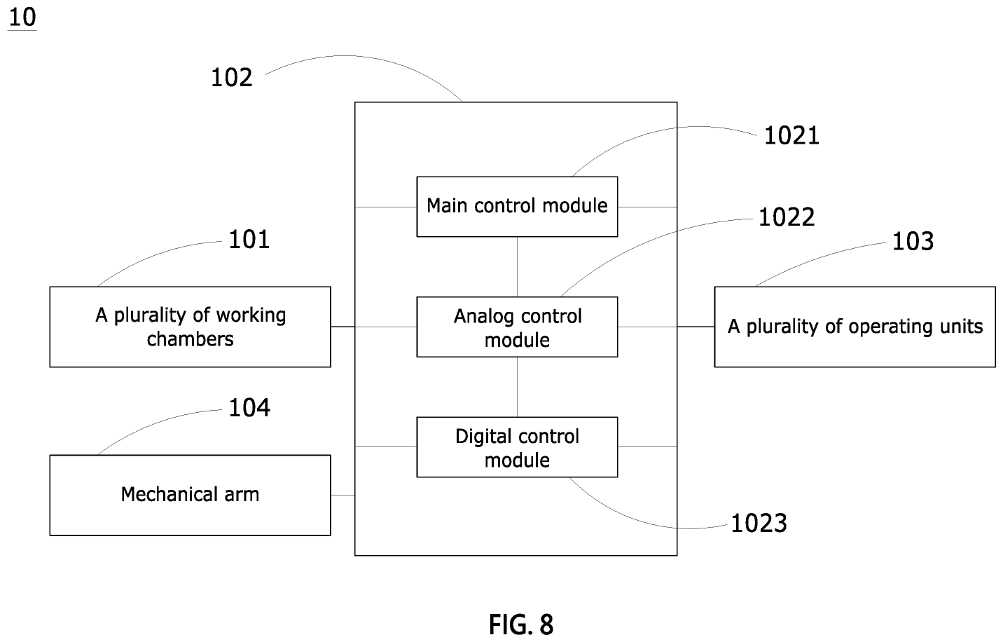

FIG. 8 is a schematic view of the composition of the semiconductor machine system in accordance with one embodiment of the present invention. Referring to FIG. 8, the semiconductor machine system 10 further comprises a mechanical arm 104, wherein the mechanical arm 104 uses a servo motor as a driving power source. In this way, the mechanical arm 104 of one embodiment of the present invention may be controlled by the servo motor to achieve full servoization, so that all positions may be controlled quickly in place. In addition, the control host 102 may receive the feedback signals sent by the mechanical arm 104 in real time, and the overall system operation and execution may be sped up by the precise feedback signals.

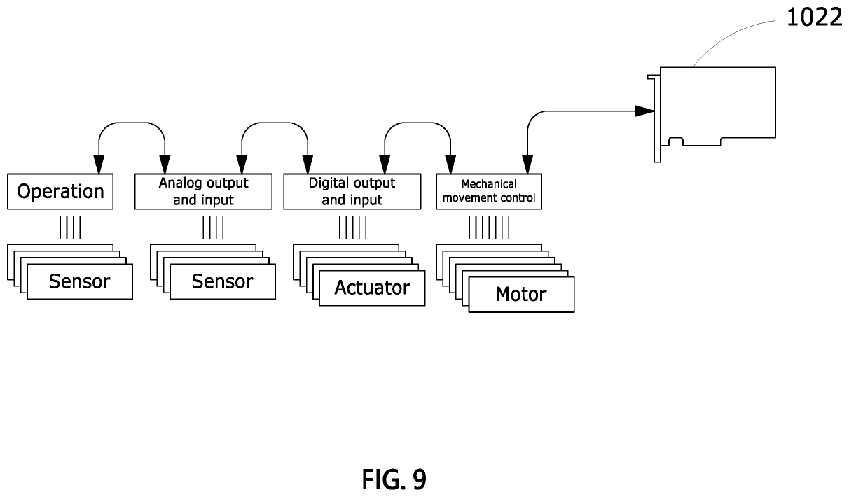

FIG. 9 is a schematic view of the coupling of the analog control module. Referring to FIG. 9, according to one embodiment of the present invention, the analog control module 1022 is mainly hardware in the form of an interface card, and is installed inside the control host 102 of the present invention in the form of a single interface card. In one embodiment of the present invention, the advantage of adopting the distributed coupling method is that the analog control module 1022 is only necessary to be coupled with one of the external devices which are to be coupled to the control host 102. As shown in FIG. 9, one of the devices coupled to the analog control module 1022 may further be coupled with other devices, so that the control host 102 does not need to be equipped with multiple interface cards and then couple the multiple interface cards to external devices as in the old machine, so that the present invention may realize the serial interface coupling to couple multiple external devices. In this way, the distributed structure of the embodiment may effectively reduce the complexity of the overall circuit wiring, thereby reducing the system failure rate and the difficulty of inspection and repair.

In summary, according to one embodiment of the present invention, the control host 102 utilizes the distributed coupling mode, eliminating the need to install multiple interface cards for coupling to external devices as in the old machine which resulted in increased coupling complexity. Therefore, the coupling complexity of the control host 102 to the external devices may be significantly reduced, and the overall size of the semiconductor machine 10 may be effectively reduced, thereby increasing the number of machines which could be placed in a fixed space. The driving power source of the mechanical arm 104 of the semiconductor machine system 10 is a servo motor. Since the servo motor adopts closed-loop control (for example, a built-in encoder) processing, and the pulse signal is used to switch the current trigger, the servo motor may rotate proportionally with the pulse signal, thus achieving precise position and speed control with good stability, and could provide the semiconductor machine system 10 with the correct way to receive the feedback signals from the mechanical arm 104 for further precise control of the mechanical arm 104.

In one embodiment of the present invention, a manufacturing method utilizing the aforementioned semiconductor machine system 10 is provided, and the manufacturing method comprises the following steps: driving the wafer exchange chamber 1014 of the semiconductor machine system 10 by the main control unit 1033 and the gas control unit 1032 of the semiconductor machine system 10 so that the wafer exchange chamber 1014 is depressurized, placed with materials, and vacuumed before opening; controlling the wafer transfer chamber 1013 of the semiconductor machine system 10 by the main control unit 1033 so that the mechanical arm 104 of the semiconductor machine system 10 carries the materials and moves to a positioning position; and controlling the wafer transfer chamber 1013 by the main control unit 1033 so that the mechanical arm 104 picks and places a board, and after placing the materials in the photoresist stripping chambers of the semiconductor machine system 10, a plasma processing is performed on the materials by the RF plasma unit 1031 of the semiconductor machine system 10.

In one embodiment of the present invention, the manufacturing method further comprising: confirming whether new materials are placed in a shuttle chamber; if the new material has been placed, after the main control unit 1033 and the gas control unit 1032 control the wafer exchange chamber 1014 to be vacuumed, a carrying platform of the wafer exchange chamber 1014 moves downward in a rotational manner; and if the new material is not placed, the main control unit 1033 confirms whether to continue the manufacturing method by a display screen.

In one embodiment of the present invention, the manufacturing method further comprising: controlling an opening timing of vacuum air valves of the primary photoresist stripping chamber (back chamber) and the secondary photoresist stripping chamber (side chamber) by the main control unit 1033 and the gas control unit 1032.

In one embodiment of the present invention, the manufacturing method further comprising: controlling a wafer carrier exchange table of the wafer exchange chamber 1014 to exchange the materials by the main control unit 1033, and when the wafer carrier exchange table reaches the positioning position, the wafer carrier exchange table raises in a rotational manner; controlling the movement of the mechanical arm 104 by the main control unit 1033; and driving the wafer exchange chamber 1014 to open after depressurized by the main control unit 1033 and the gas control unit 1032.

In one embodiment of the present invention, the manufacturing method further comprising: after the plasma processing performed on the materials is finished by the RF plasma unit 1031, the main control unit 1033 controls the wafer cooling chamber 1015 of the semiconductor machine system 10 to control the cooling time.

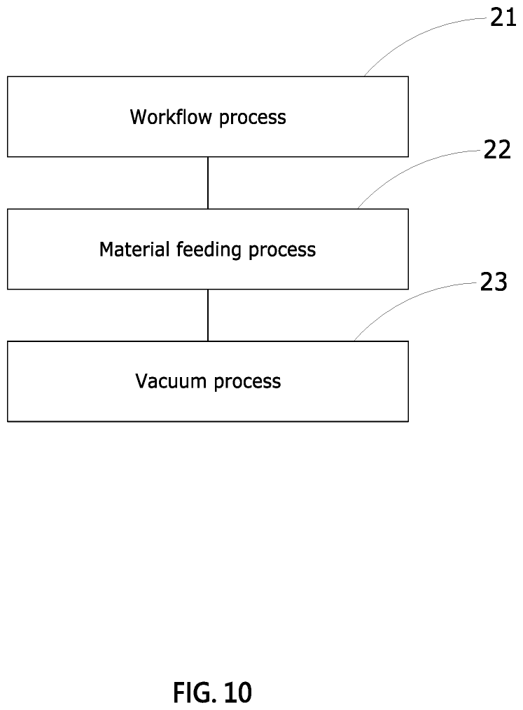

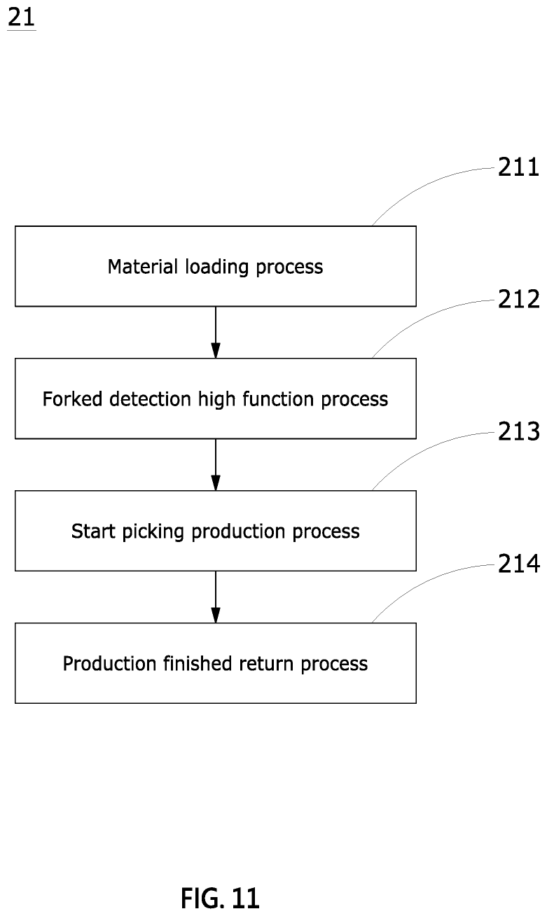

FIG. 10 is the processing method and steps of the semiconductor machine system. FIG. 11 is a flowchart of the workflow processing steps. Referring to FIGS. 10 and 11, the processing method and steps of the semiconductor machine system 10 according to one embodiment of the present invention is shown. The embodiment shown in FIG. 10 comprises: workflow process 21, material feeding process 22, and vacuum process 23. The workflow process 21 means the process in which the main control unit 1033 controls each element coupled to the main control unit 1033 to generate corresponding movements or operations. The material feeding process 22 means the process in which the main control unit 1033 controls each element coupled to the main control unit 1033 so that the materials to be processed may enter each chamber smoothly. The vacuum process 23 means that the main control unit 1033 controls each element coupled with the main control unit 1033, so that each chamber may be vacuumed and depressurized under appropriate conditions to avoid damaging the corresponding vacuum pump or polluting the chamber due to improper pressure changes. Therefore, the workflow process 21, the material feeding process 22, and the vacuum process 23 are not separate and sequential steps, but each process operates interactively or simultaneously at different time points. The relevant processing and steps are described as follows.

(1) The workflow process 21, which comprises:

material loading process 211: the main control unit 1033 and the gas control unit 1032 are mainly used to drive the wafer exchange chamber 1014 to operate, so that the wafer exchange chamber 1014 may be depressurized, the machine operator (human-machine interface) may be asked after loading of materials, and the wafer exchange chamber 1014 may be re-vacuumed and lowered for operation (referring to the exchange between the finished and unfinished wafers of the machine must be lowered before the exchange could be performed) before opening the door: in addition, the main control unit 1033 controls the wafer carrier exchange table in the wafer exchange chamber 1014 to perform the rotational operation, which may be done by rotating 180 degrees to exchange the inner and outer wafers, so that after the wafer carrier exchange table reaches the positioning position, the raising operation may be performed in a rotational manner at the same time, and then, the main control unit 1033 is utilized for precise positioning operation of the mechanical arm 104, and the wafer exchange chamber 1014 is driven by using the main control unit 1033 and the gas control unit 1032 to achieve the operation of raising and opening the door after being depressurized;

forked detection high function process 212: the main control unit 1033 is used to control the operations of the wafer transfer chamber 1013 so that the two forks of the mechanical arm 104 respectively carry two wafers, and in one embodiment, when looking for the output positioning position, the two forks have to be positioned separately;

start picking production process 213: the main control unit 1033 is used to control the operation of the wafer transfer chamber 1013, so that the mechanical arm 104 may process the operations of picking and placing the board, and the related operations of the secondary photoresist stripping chamber 1012 and the related operations of the primary photoresist stripping chamber 1011 are carried out successively, wherein when carrying out the aforementioned operations, the main control unit 1033 is used together with the gas control unit 1032 to control the primary photoresist stripping chamber 1011 to complete the material loading operation, and then the RF plasma unit 1031 is further used to sequentially complete the operations of the door closing process, driving the plasma generator to operate, reading the production processing formula, waiting for the time of the plasma generator, and waiting for the time of the plasma processing, etc., and the main control unit 1033 controls the wafer cooling chamber 1015 to control the cooling operation time; in addition, the main control unit 1033 may cooperate with the gas control unit 1032 to control the primary photoresist stripping chamber 1011 to perform the operations of gas flow detection, sending reading angle instructions to the control host 102, obtaining angle values, setting analog output values, and transmitting the set analog output values, etc., and then the main control unit 1033 is used to control the wafer cooling chamber 1015 for operation cooling; in addition, the main control unit 1033 may also control the secondary photoresist stripping chamber 1012 to perform the same operation as the primary photoresist stripping chamber 1011;

and production finished return process 214: confirming whether new materials are placed in the wafer exchange chamber 1014, if yes, after the main control unit 1033 and the gas control unit 1032 are used to control the wafer exchange chamber 1014 to be vacuumed, the carrying platform in the chamber would rotate and descend at the same time to continue the operation; if not, the main control unit 1033 may pop up an inquiry window through the display screen to check the operation, and the main control unit 1033 and the gas control unit 1032 are used again to control the wafer exchange chamber 1014 to open the door and wait for the material loading, and to move downward in a rotational manner after being vacuumed.

(2) The material feeding process 22: after the main control unit 1033 is used to control the wafer exchange chamber 1014 to close the door, the main control unit 1033 and the gas control unit 1032 are used to control the wafer transfer chamber 1013 to perform the operations of the mechanical arm 104. In the embodiment, the wafer exchange chamber 1014 must be vacuumed to a preferred pressure setting value of 1.5 Torr, and after the main control unit 1033 and the gas control unit 1032 are used to control the wafer transfer chamber 1013 and the wafer exchange chamber 1014 to open the butterfly valve of the LoadLock, the wafer exchange chamber 1014 are further vacuumed to be 0.96 Torr, and then the main control unit 1033 is used to control the wafer exchange chamber 1014 to descend in a rotational manner or ascend to transfer the materials to the wafer transfer chamber 1013; and after the transfer is completed, the main control unit 1033 and the gas control unit 1032 are used to control the closing of the air butterfly valve between the wafer transfer chamber 1013 and the wafer exchange chamber 1014, so that the pressure increases to 1.1 Torr; and finally, the main control unit 1033 and the gas control unit 1032 are used to control the primary photoresist stripping chamber 1011, the secondary photoresist stripping chamber 1012, and the wafer transfer chamber 1013 to complete the operation of taking the board into the working chamber with the arm.

(3) The vacuum process 23: the main control unit 1033 and the gas control unit 1032 are used to control the opening timing of the vacuum air valves of the primary photoresist stripping chamber (back chamber) and the secondary photoresist stripping chamber (side chamber), and the main control unit 1033 and the gas control unit 1032 are used to control the wafer transfer chamber 1013 and the wafer exchange chamber 1014 to operate the opening timing of the air valves of the secondary photoresist stripping chamber (side chamber); and finally, the main control unit 1033 and the gas control unit 1032 are used to control the operations of the primary photoresist stripping chamber 1011, the secondary photoresist stripping chamber 1012, the wafer transfer chamber 1013, and the wafer exchange chamber 1014, so that the vacuum value reaches the expected data; and after the main control unit 1033 and the gas control unit 1032 are used to control the venting timing, the air valve would be opened when the primary photoresist stripping chamber (back chamber) is over pumped and then would be closed after the vacuum value is stabilized.

Based on the above description, it is clear that the concepts described in the present application may be implemented by various techniques without departing from the scope of these concepts. Furthermore, although the concepts have been described with specific reference to certain implementations, those skilled in the art would recognize that changes may be made in form and detail without departing from the scope of these concepts. In this way, the described embodiments are to be considered in all respects as illustrative rather than restrictive. Furthermore, it should be understood that the present application is not limited to the particular embodiments described above, but many rearrangements, modifications, and substitutions are possible without departing from the scope of the present invention.

The above is a detailed description of the embodiments of the present invention with reference to the drawings, but the specific composition is not limited to the embodiments, but also includes design variations within the scope of the purpose of the present invention. Furthermore, the invention may be subject to various variations within the scope of the claims, and the embodiments obtained by suitably combining the technical means revealed by different embodiments are also included in the technical scope of the present invention. In addition, configurations in which elements described in the above embodiments are exchanged with elements that exert the same effects are also included.

What is claimed is:

1. A semiconductor machine system, comprising:
a plurality of working chambers, wherein the plurality of working chambers process materials separately; and
a control host coupled to the plurality of working chambers, which comprises:
a main control module coupled to the plurality of working chambers;
an analog control module coupled to the plurality of working chambers, wherein the analog control module is detachably coupled to one or more external devices by serial interface coupling;
a digital control module coupled to the plurality of working chambers, wherein the main control module, the analog control module, and the digital control module are coupled to each other; and
a plurality of operating units coupled to at least one of the main control module, the analog control module, and the digital control module, respectively, to control the plurality of working chambers for processing the materials by the main control module, the analog control module and the digital control module.

2. The semiconductor machine system of claim 1, wherein
the plurality of working chambers comprises at least one of a primary photoresist stripping chamber, a secondary photoresist stripping chamber, a wafer transfer chamber, a wafer exchange chamber, and a wafer cooling chamber;
wherein the main control module is coupled to at least one of the primary photoresist stripping chamber, the secondary photoresist stripping chamber, the wafer transfer chamber, the wafer exchange chamber, and the wafer cooling chamber, respectively, for control;
the analog control module is coupled to at least one of the primary photoresist stripping chamber, the secondary photoresist stripping chamber, the wafer transfer chamber, and the wafer exchange chamber, respectively, for control; and
the digital control module is coupled to at least one of the primary photoresist stripping chamber, the secondary photoresist stripping chamber, the wafer transfer chamber, the wafer exchange chamber, and the wafer cooling chamber, respectively, for control.

3. The semiconductor machine system of claim 1, wherein the plurality of operating units further comprises:
a RF plasma unit, which comprises a plasma generator and a control circuit;
a gas control unit, which comprises a solenoid valve, a flow valve, and a barometer; and
a main control unit, which comprises a processor and a storage device, wherein the storage device is coupled to the processor and stores a plurality of instructions which, when executed by the processor, cause the processor to control the RF plasma unit, the gas control unit, and the plurality of working chambers.

4. The semiconductor machine system of claim 3, wherein the main control module is coupled to the RF plasma unit, the main control unit, and the gas control unit, respectively, the analog control module is coupled to the RF plasma unit and the gas control unit, respectively, and the digital control module is coupled to the RF plasma unit, the main control unit, and the gas control unit.

5. The semiconductor machine system of claim 1, further comprising:
a mechanical arm, which uses a servo motor as a driving power source, and the control host receives feedback signals from the mechanical arm in real time.

6. A manufacturing method utilizing a semiconductor machine system, comprising the following steps:
driving a wafer exchange chamber of the semiconductor machine system by a main control unit and a gas control unit of the semiconductor machine system so that the wafer exchange chamber is depressurized, placed with materials, and vacuumed before opening;
controlling a wafer transfer chamber of the semiconductor machine system by the main control unit so that a mechanical arm of the semiconductor machine system carries the materials and moves to a positioning position; and
controlling the wafer transfer chamber by the main control unit so that the mechanical arm picks and places a board, and after placing the materials in photoresist stripping chambers of the semiconductor machine system, a plasma processing is performed on the materials by a RF plasma unit of the semiconductor machine system.

7. The manufacturing method of claim 6, further comprising:
confirming whether new materials are placed in a shuttle chamber;
if the new material has been placed, after the main control unit and the gas control unit control the wafer exchange chamber to be vacuumed, a carrying platform in the wafer exchange chamber moves downward in a rotational manner; and
if the new material is not placed, the main control unit confirms whether to continue the manufacturing method by a display screen.

8. The manufacturing method of claim 6, further comprising:
controlling an opening timing of vacuum air valves of a primary photoresist stripping chamber (back chamber) and a secondary photoresist stripping chamber (side chamber) by the main control unit and the gas control unit.

9. The manufacturing method of claim 6, further comprising:
controlling a wafer carrier exchange table in the wafer exchange chamber to exchange the materials by the main control unit, and when the wafer carrier exchange table reaches the positioning position, the wafer carrier exchange table raises in a rotational manner;
controlling the movement of the mechanical arm by the main control unit; and
driving the wafer exchange chamber to open after depressurized by the main control unit and the gas control unit.

10. The manufacturing method of claim 6, further comprising:
after the plasma processing performed on the materials is finished by the RF plasma unit, the main control unit controls the wafer cooling chamber of the semiconductor machine system to control a cooling time.
